(19) United States
(12) Patent Application Publication
(10) Pub. No.: US 2007/0010079 A1
(43) Pub. Date: Jan. 11, 2007

(54) Method for fabricating semiconductor device

(76) Inventors: Hidehiko Ichiki, Kiyotake-cho (JP); Teruhisa Fukuda, Miyazaki (JP)

Correspondence Address: VOLENTINE FRANCOS & WHITT, PLLC;One Freedom Square, Suite 1260, 11951 Freedom Drive, Reston, VA, 20190, US

(21) Appl. No.: 11/174,586

(22) Filed: Jul. 6, 2005

(51) Int. Cl. H01L 21/465

(52) U.S. Cl. 438/585; 438/906; 438/745; 438/770

(57) ABSTRACT

According to the present invention, a method for fabricating a semiconductor device includes the steps of: providing a semiconductor substrate; providing a diffusion layer in the semiconductor substrate; providing a first oxide layer on the semiconductor substrate; providing a poly-silicon layer on the first oxide layer; introducing phosphorus into the poly-silicon layer; selectively removing the poly-silicon layer to form a conductive pattern; removing the first oxide layer from the semiconductor substrate; and performing a cleaning process within approximately two hours since the first oxide layer is removed.

### TECHNICAL FIELD OF THE INVENTION

The present invention relates to an advanced method for fabricating a semiconductor device.

### BACKGROUND OF THE INVENTION

In a LSI fabrication process, a number of semiconductor devices are formed on a single wafer. According to a conventional method for fabricating a semiconductor device, a well region is formed in a semiconductor substrate; and a diffusion layer may be formed in the well region. After that, a gate oxide layer is formed over the semiconductor substrate, then a poly-silicon layer is formed on the gate oxide layer, and then, phosphorus is diffused into the poly-silicon layer. Subsequently, a gate electrode is formed from the poly-silicon layer, and the gate oxide layer is removed from the semiconductor substrate. A chemical silicon oxide layer may be formed over the semiconductor substrate after the gate oxide layer is removed. Thus fabricated wafer is cleaned, and then, a thermal treatment is carried out to form a silicon oxide layer over the gate electrode and the semiconductor substrate.

According to the above described conventional method, phosphorus may be diffused from poly-silicon in the air after the gate oxide layer is removed. The diffused phosphorus is stuck onto a surface of the chemical silicon oxide layer. The cleaning process is not good enough to remove the diffused phosphorus out of the semiconductor substrate. In a subsequent thermal treatment, the diffused phosphorus enters or diffuses into the semiconductor substrate, and the semiconductor substrate is contaminated. Therefore, a resistance value of the diffusion layer in the substrate is increased and becomes unstable. As a result, operation and performance of the fabricated device would be deteriorated.

### OBJECTS OF THE INVENTION

Accordingly, an object of the present invention is to provide a method for fabricating a semiconductor device in which a diffusion layer has a stable resistance value.

Another object of the present invention is to provide a method for fabricating a semiconductor device in which a negative affection from diffused phosphorus can be reduced.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to the present invention, a method for fabricating a semiconductor device includes the following steps:

(1) providing a semiconductor substrate;

(2) providing a diffusion layer in the semiconductor substrate;

(3) providing a first oxide layer on the semiconductor substrate;

(4) providing a poly-silicon layer on the first oxide layer;

(5) diffusing phosphorus into the poly-silicon layer;

(6) selectively removing the poly-silicon layer to form a conductive pattern;

(7) removing the first oxide layer from the semiconductor substrate; and

(8) performing a cleaning process within approximately two hours since the first oxide layer is removed.

The diffusion layer may be of P-conductive type. The first oxide layer may be a gate oxide layer, and the conductive pattern may be a gate electrode. The semiconductor substrate is of P-conductive type.

The method may further include a step, following the cleaning process, of performing a thermal treatment to form a second oxide layer over the conductive pattern and the semiconductor substrate. The method may still further include a step of providing a well region in the semiconductor substrate, wherein the diffusion layer is formed in the well region. The method may further include a step of preserving the semiconductor substrate after the cleaning process for a certain period of time until the thermal treatment is carried out.

The first oxide layer can be removed using fluorochemical agent. The cleaning process may be carried out in a SPM (sulfuric acid-hydrogen peroxide) cleaning process.

### BRIEF DESCRIPTION OF THE DRAWINGS

FIGS. 1A-1K are cross-sectional views showing fabrication steps of a semiconductor device according to a preferred embodiment of the present invention.

FIG. 2 is a flow chart showing fabrication steps of the preferred embodiment, shown in FIGS. 1A-1K.

FIG. 3 is a graph showing difference of performance between the present invention and conventional technology.

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions; The following detailed description is, therefore, not to be taken in a limiting sense, and scope of the present inventions is defined only by the appended claims.

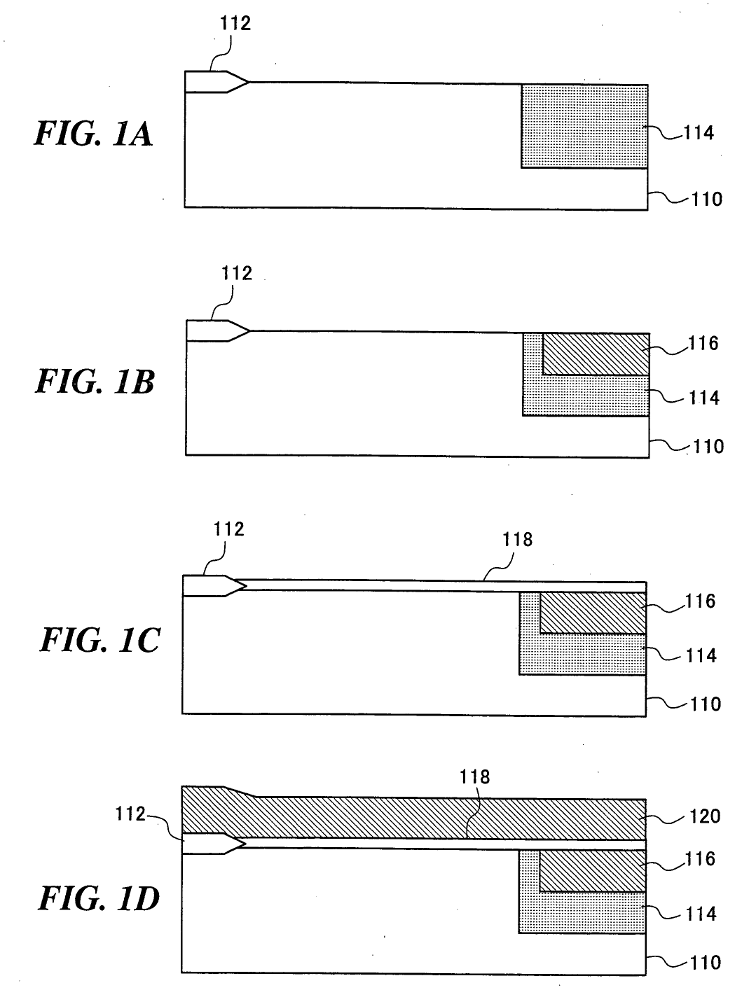

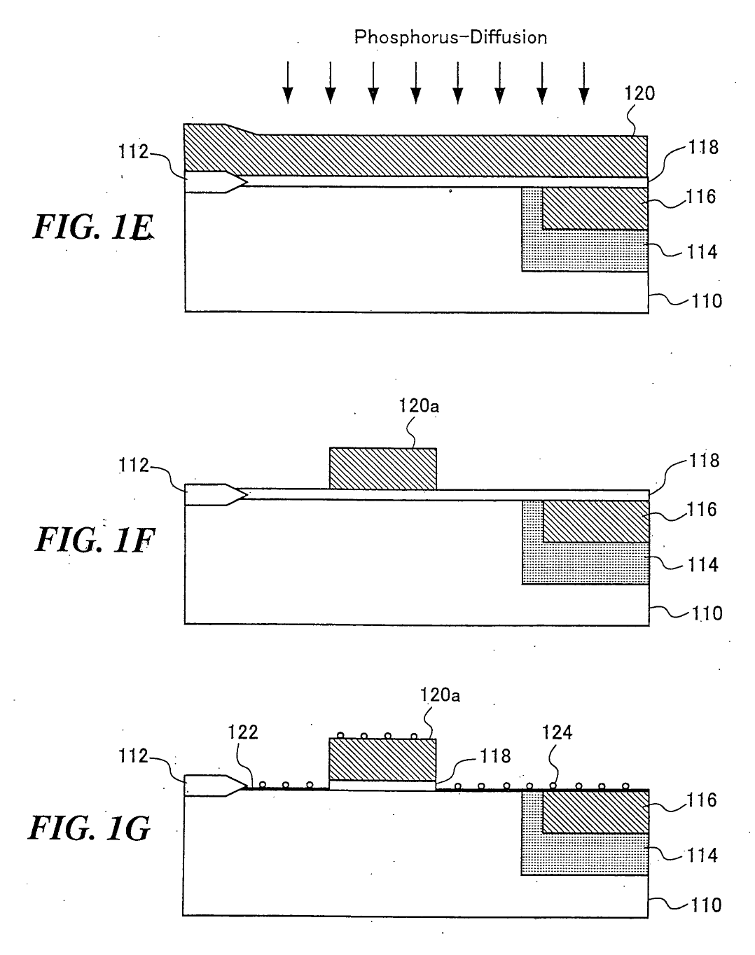

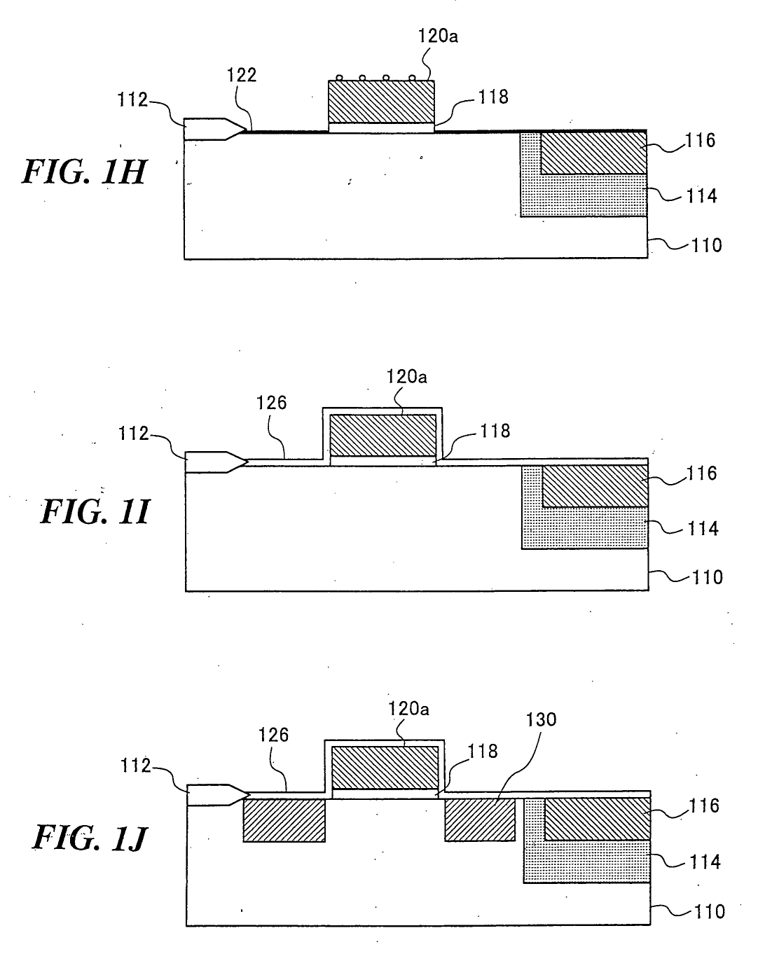

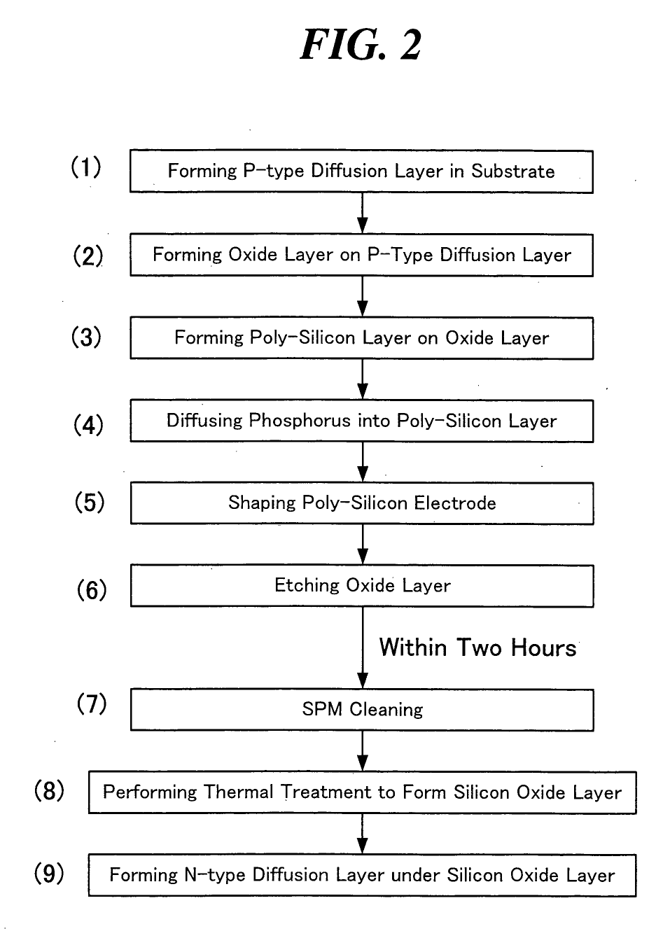

FIGS. 1A-1K are cross-sectional views showing fabrication steps of a semiconductor device according to a preferred embodiment of the present invention. FIG. 2 is a flow chart showing fabrication steps of the preferred embodiment, shown in FIGS. 1A-1K. Now, fabricating steps of a semiconductor device according to the present invention are described referring to FIGS. 1A-1K and 2.

First, a p-type semiconductor substrate 110 having a device isolation region 112, which may be a LOCOS oxide layer, is provided. An N-well region 114 is formed in the semiconductor substrate 110 by photolithographic process, ion-implantation process and diffusion process, as shown in FIG. 1A. Next, a p-type diffusion layer 116 is formed in the N-well region 114, as shown in FIG. 1B. According to the present invention, a n-type semiconductor substrate may be used instead of p-type.

Subsequently, as shown in FIG. 1C, a gate oxide layer 118 is formed over the semiconductor substrate. Next, a poly-silicon layer 120 is formed on the gate oxide layer 118 by a CVD process, as shown in FIG. 1D. After that, phosphorus is diffused into the poly-silicon layer 120, as shown in FIG. 1F.

Next, as shown in FIG. 1G, the poly-silicon layer 120 is selectively removed to form a gate electrode (conductive pattern) 120a by a photolithographic process and an etching process. After that, the gate oxide layer 118 is removed from the semiconductor substrate 110 using fluorochemical agent. At this time, a chemical silicon oxide layer 122 is formed over the semiconductor substrate 110, as shown in FIG. 1H. After the gate oxide layer 118 is removed, phosphorus may be diffused (come out) from poly-silicon 120a in the air, and the diffused phosphorus is stuck onto a surface of the chemical silicon oxide layer 122.

Thus fabricated substrate is cleaned within approximately two hours since the gate oxide layer 118 is removed in a SPM (sulfuric acid-hydrogen peroxide) cleaning process, as shown in FIG. 1I. After the gate oxide layer 118 is removed from the semiconductor substrate 110, if it takes many hours until the cleaning process is carried out, it would be hard to take out phosphorus from the chemical silicon oxide layer 122 completely. Such phosphorus may be diffused (Out-Diffusion) or infiltrated into the semiconductor substrate 110, P-type diffusion layer 116 and N-well region 114. According to the present invention, the substrate (wafer) is cleaned before phosphorus is deeply diffused or infiltrated into the chemical silicon oxide layer 122. The cleaning process can be said “pre-cleaning”, which is carried out before a thermal treatment.

The substrate can be preserved for a relatively long time after the cleaning process is completed, for example, more than four hours until a subsequent process is carried out. The preservation time can be extended.

After the cleaning process or preservation process, a thermal treatment is carried out to form a silicon oxide layer 126 over the gate electrode 120a and the semiconductor substrate 110, as shown in FIG. 1J. Subsequently, a N-type diffusion layer 130 is formed under the silicon oxide layer 126 by photolithographic process and ion-implantation process, as shown in FIG. 1K.

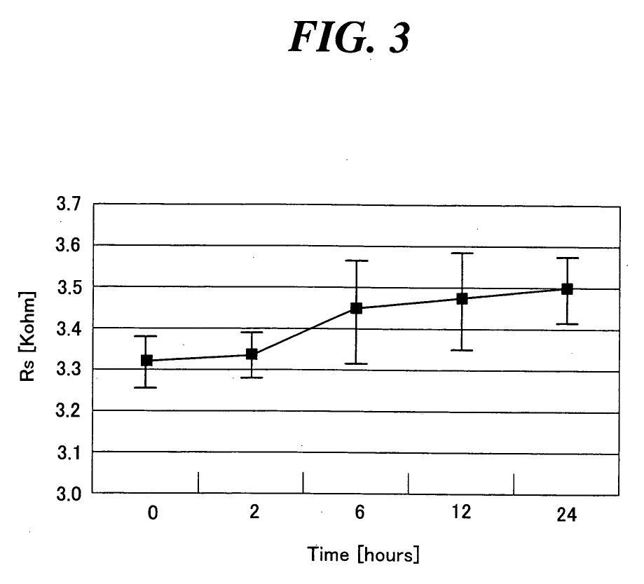

FIG. 3 is a graph showing difference of performance between the present invention and conventional technology. In the graph, “Time” represents a period of time since a gate oxide layer is removed to a cleaning process, which corresponds to a period of time between step (6) and step (7) in FIG. 2. “Rs” represents a resistance value of the p-type diffusion layer 116. It is clear from the graph, when the substrate (wafer) is cleaned within (no later than) approximately two hours since the gate oxide layer 118 is removed, a resistance value of the p-type diffusion layer 116 is not increased so much and is stable in level. As a result, operation and performance of the fabricated device would be better than conventional technology. It can be thought that according to the present invention, diffused phosphorus is completely removed out of the chemical oxide layer 122 before a thermal treatment.

The present invention is applicable to another case in which phosphorus is implanted but not diffused into a poly-silicon layer. Other type of introduction techniques can be applicable. The present invention is also useful to reduce an amount of contamination caused by phosphorus diffused from a silicon substrate, in which phosphorus has been implanted into the substrate.

What is claimed is:

1. A method for fabricating a semiconductor device, comprising:
providing a semiconductor substrate;
providing a diffusion layer in the semiconductor substrate;
providing a first oxide layer on the semiconductor substrate;
providing a poly-silicon layer on the first oxide layer;
introducing phosphorus into the poly-silicon layer;
selectively removing the poly-silicon layer to form a conductive pattern;
removing the first oxide layer from the semiconductor substrate; and
performing a cleaning process within approximately two hours since the first oxide layer is removed.

2. A method for fabricating a semiconductor device according to claim 1, wherein
the diffusion layer is of P-conductive type.

3. A method for fabricating a semiconductor device according to claim 1, further comprising:
after the cleaning process, performing a thermal treatment to form a second oxide layer over the conductive pattern and the semiconductor substrate.

4. A method for fabricating a semiconductor device according to claim 1, wherein
the first oxide layer is a gate oxide layer, and
the conductive pattern is a gate electrode.

5. A method for fabricating a semiconductor device according to claim 1, wherein
the first oxide layer is removed using fluorochemical agent.

6. A method for fabricating a semiconductor device according to claim 1, wherein
the cleaning process is carried out in a SPM (sulfuric acid-hydrogen peroxide) cleaning process.

7. A method for fabricating a semiconductor device according to claim 1, wherein
the semiconductor substrate is of P-conductive type.

8. A method for fabricating a semiconductor device according to claim 1, further comprising:
providing a well region in the semiconductor substrate, wherein
the diffusion layer is formed in the well region.

9. A method for fabricating a semiconductor device according to claim 1, wherein
phosphorus is diffused into the semiconductor substrate.

10. A method for fabricating a semiconductor device according to claim 3, further comprising:
preserving the semiconductor substrate after the cleaning process for a certain period of time until the thermal treatment is carried out.

11. A method for fabricating a semiconductor device according to claim 1, wherein
a chemical silicon oxide layer is formed over the semiconductor substrate after the first oxide layer is removed.

12. A method for fabricating a semiconductor device, comprising:
providing a semiconductor substrate;
providing an N-well region in the semiconductor substrate;
providing a p-type diffusion layer in the N-well region;
providing a gate oxide layer over the semiconductor substrate,
providing a poly-silicon layer on the gate oxide layer;
diffusing phosphorus into the poly-silicon layer;
selectively removing the poly-silicon layer to form a gate electrode;
removing the gate oxide layer from the semiconductor substrate, so that a chemical silicon oxide layer is formed over the semiconductor substrate;
performing a cleaning process within approximately two hours since the gate oxide layer is removed; and
performing a thermal treatment to form a silicon oxide layer over the gate electrode and the semiconductor substrate.

13. A method for fabricating a semiconductor device according to claim 12, wherein
the cleaning process is carried out in a SPM (sulfuric acid-hydrogen peroxide) cleaning process.

14. A method for fabricating a semiconductor device according to claim 12, further comprising:
preserving the semiconductor substrate after the cleaning process for a certain period of time until the thermal treatment is carried out.

15. A method for fabricating a semiconductor device according to claim 12, wherein
the gate oxide layer is removed using fluorochemical agent.
